(19) United States
(12) Patent Application Publication
(10) Pub. No.: US 2026/0213300 A1
(43) Pub. Date: Jul. 23, 2026

(54) BATTERY PACK AND COOLING SYSTEM INCLUDING THE SAME

(71) Applicant: SK ON CO., LTD., Seoul (KR)

(72) Inventors: Jae In KIM, Daejeon (KR); Do Yun KWAK, Daejeon (KR); Se Hyeon KIM, Daejeon (KR); Woo Jin LEE, Daejeon (KR)

(21) Appl. No.: 19/315,657

(22) Filed: Sep. 1, 2025

(30) Foreign Application Priority Data
Jan. 17, 2025 (KR) 10-2025-0007487

(51) Int. Cl. H01M 10/6568; H01M 10/42; H01M 10/613; H01M 50/204; H05K 7/20

(52) U.S. Cl. CPC H01M 10/6568; H01M 10/425; H01M 10/613; H01M 50/204; H01M 2010/4271; H05K 7/20927

(57) ABSTRACT

A battery pack and a cooling system including the battery pack are disclosed. A battery pack according to the present disclosure includes: a pack housing configured to receive coolant for immersion cooling; a battery module accommodated within the pack housing; and an electrical component accommodated within the pack housing and disposed separately from the battery module, wherein the pack housing includes: a battery module housing configured to accommodate the battery module; and an electrical component housing configured to accommodate the electrical component, wherein the coolant flows through the battery module housing and the electrical component housing.

### CROSS REFERENCE TO RELATED APPLICATION

This application claims priority under 35 U.S.C. § 119 to Korean Patent Application No. 10-2025-0007487, filed on Jan. 17, 2025, the disclosure of which is incorporated herein by reference in its entirety.

### BACKGROUND OF THE INVENTION

### 1. Field of the Invention

The present disclosure relates to a battery pack and a cooling system including the same.

### 2. Description of the Related Art

Recently, with the increasing demand for fast charging of electric vehicle batteries, liquid immersion cooling methods have been developed to replace conventional indirect cooling methods.

Generally, liquid immersion cooling battery systems include a reservoir structure for maintaining the liquid level, filter foreign substances, and prevent bubble generation inside the fluid.

However, due to limited vehicle space and weight constraints, the liquid immersion cooling battery system should be minimized.

In addition, during fast charging of the battery system, electrical components included in the liquid immersion cooling battery system may be overloaded, and thus, a system capable of efficiently cooling the battery and the electrical components is required.

### SUMMARY OF THE INVENTION

According to one aspect of the present disclosure, there may be provided a battery pack with increased space efficiency for immersion cooling and a cooling system including the same.

A battery pack according to an embodiment of the present disclosure may include: a pack housing configured to receive coolant for immersion cooling; a battery module accommodated within the pack housing; and an electrical component accommodated within the pack housing and disposed separately from the battery module, wherein the pack housing may include: a battery module housing configured to accommodate the battery module; and an electrical component housing configured to accommodate the electrical component, wherein the coolant may flow through the battery module housing and the electrical component housing.

The battery pack may further include a built-in pump accommodated in a pump case that forms part of the pack housing; and a first valve configured to adjust the flow rate of the coolant between the built-in pump and the battery module housing.

The battery pack may further include a circulation flow path connected to the pack housing and through which the coolant flows, wherein the circulation flow path may include: a circulation supply flow path connected to the electrical component housing; and a circulation discharge flow path connected to the battery module housing.

The coolant may sequentially flow through the circulation supply flow path, the electrical component housing, the battery module housing, and the circulation discharge flow path.

The electrical component housing may be located in front of the battery module housing.

The battery pack may further include a battery pack cooling flow path disposed within the pack housing, wherein the battery pack cooling flow path may include: a first battery pack cooling flow path configured to connect the electrical component to the built-in pump; and a second battery pack cooling flow path configured to connect the built-in pump to the battery module housing.

The first valve may be located in the second battery pack cooling flow path.

The pack housing may include a door openably coupled to an open upper portion thereof, wherein the door may include: a module housing body door disposed at an open upper portion of the battery module housing; and an electrical component housing body door disposed at an open upper portion of the electrical component housing.

The electrical component may include: an electrical component case connected to the circulation supply flow path and configured to receive the coolant; a power relay assembly accommodated within the electrical component case; and a battery management system disposed adjacent to the power relay assembly.

The battery management system may be disposed in a power relay assembly (PRA) recess formed in the power relay assembly.

The electrical component case may include: a lower case having a coolant outlet connected to the first battery pack cooling flow path; and an upper case coupled to an open upper portion of the lower case and having a coolant inlet connected to the circulation supply flow path.

The electrical component may include a bracket disposed in the power relay assembly recess, and the battery management system may be supported by the bracket.

The battery module may include: a battery module case; and battery cells accommodated in the battery module case, wherein the battery cells may be stacked in a front-back direction.

The battery module housing and the electrical component housing may be disposed adjacent to each other.

The electrical component and the battery module may be connected by a bus bar embedded in a bottom surface of the pack housing.

A battery pack cooling system according to an embodiment of the present disclosure may include: a battery pack configured to separately accommodate a battery module and an electrical component electrically connected to the battery module, and to receive coolant for immersion cooling; a circulation flow path connected to the battery pack; a cooler disposed in the circulation flow path and configured to cool the coolant; and a reservoir tank disposed in the circulation flow path and configured to store the coolant discharged from the battery pack.

The circulation flow path may include: a circulation supply flow path connected to the electrical component; and a circulation discharge flow path connected to a battery module housing configured to accommodate the battery module.

The battery pack may further include a second valve disposed in the circulation discharge flow path, wherein the second valve may be configured to adjust a flow rate of the coolant between the battery module housing and the reservoir tank.

The battery pack may include a pack housing configured to separately accommodate the battery module and the electrical component, wherein the pack housing may include a battery module housing configured to accommodate the battery module; and an electrical component housing configured to accommodate the electrical component, wherein the coolant may flow through the battery module housing, the circulation flow path, and the electrical component housing.

The pack housing may include a door openably coupled to an open upper portion thereof, wherein the door may include: a module housing body door disposed at an open upper portion of the battery module housing; and an electrical component housing body door disposed at an open upper portion of the electrical component housing.

The battery pack and the cooling system including the same according to an embodiment of the present disclosure may increase space efficiency for immersion cooling.

The battery pack and the cooling system including the same according to the present disclosure may achieve overall space and weight reduction by separating the cooling space of the battery from the electrical components.

The battery pack and the cooling system including the same according to the present disclosure may improve maintenance convenience by enabling separate maintenance of the battery and the electrical components.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a schematic view of a battery pack cooling system according to an embodiment of the present disclosure;

FIG. 2 is a view illustrating a battery pack included in a battery pack cooling system;

FIG. 3 is a view illustrating a pack housing that forms a battery pack;

FIG. 4 is a cross-sectional view illustrating the battery pack shown in FIG. 2, taken along line A1-A2;

FIG. 5 is a block diagram of a battery pack cooling system according to an embodiment of the present disclosure;

FIG. 6 is a view illustrating an electrical component included in the battery pack; and

FIG. 7 is an exploded perspective view illustrating the electrical component shown in FIG. 6.

### DETAILED DESCRIPTION OF THE INVENTION

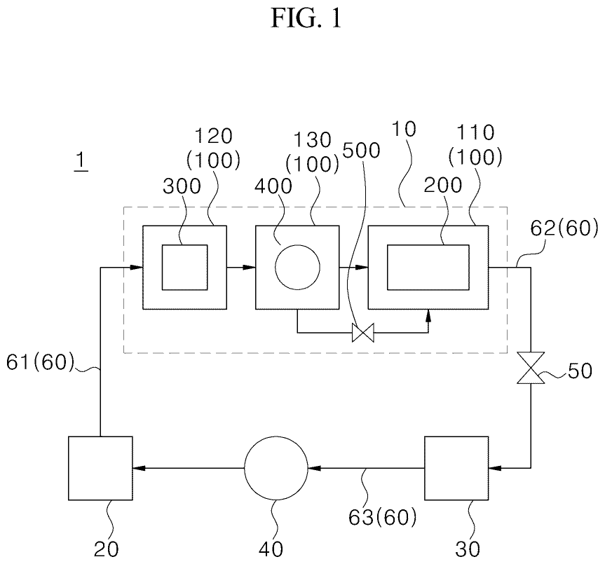

Hereinafter, embodiments of the present disclosure will be described in detail with reference to FIGS. 1 to 7. However, these embodiments are merely illustrative, and the present disclosure is not limited to the specific embodiments described as examples.

A battery module 200 applicable to the present disclosure may be applied to pouch cells, cylindrical cells, square cells, and the like. Battery cells 220 that form the battery module may be of a winding type, a stacking type, a zigzag folding type, or a stack-folding type.

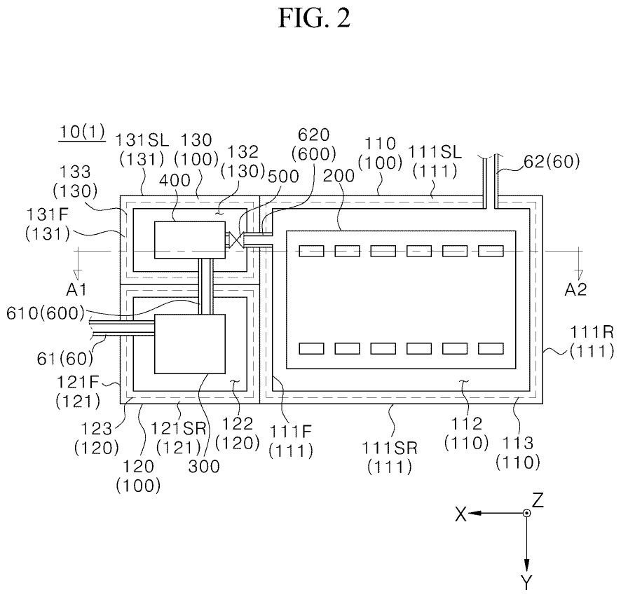

In this specification, the coordinate system may be a Cartesian coordinate system. In this specification, the front-back direction and the left-right direction may be set based on FIG. 2.

The front-back direction may be parallel to the X-axis. In some embodiments, a positive X-axis direction may represent the forward direction, and a negative X-axis direction may represent the rearward direction.

The left-right direction may be parallel to the Y axis. In some embodiments, a positive Y-axis may represent the leftward direction, and a negative Y-axis may represent the rightward direction.

The up-down direction may be parallel to the Z-axis. In some embodiments, a positive Z-axis direction may represent the upward direction, and a negative Z-axis direction may represent the downward direction. The Y-axis may be perpendicular to both the X-axis and the Z-axis.

Referring to FIGS. 1 and 2, a battery pack cooling system 1 according to the present disclosure may include the battery module 200 and an electrical component 300, which are disposed in separate and independent spaces. A coolant circulating through the battery pack cooling system 1 may sequentially flow through the electrical component 300 and the battery module 200.

The battery module 200 and the electrical component 300 may each be in an immersion-cooled state through the coolant within their respective separate spaces. The coolant may be a non-conductive liquid applied to perform immersion cooling on the battery pack cooling system 1. In FIG. 1, the arrows indicate the flow of the coolant.

The battery pack cooling system 1 may include a battery pack 10. The battery pack 10 may define a space in which the coolant is supplied and liquid immersion cooling is performed. The battery pack 10 may be partitioned into a plurality of spaces.

In some embodiments, the plurality of partitioned spaces may include a space for accommodating the battery module 200, a space for accommodating the electrical component 300, and a space for accommodating a built-in pump 400 disposed between the battery module 200 and the electrical component 300.

The battery pack 10 may include a pack housing 100. The pack housing 100 may define a hollow portion. The pack housing 100 may include a plurality of spaces. The pack housing 100 may be partitioned into a plurality of spaces. The plurality of spaces formed in the pack housing 100 may include a plurality of housings 110, 120 and 130. The plurality of housings 110, 120 and 130 may be disposed adjacent to one another.

The pack housing 100 may include a battery module housing 110. The battery module housing 110 may be formed with a hollow structure. The battery module housing 110 may be openable in one direction. In some embodiments, the battery module housing 110 may be configured to be openable in an upward direction. The battery module housing 110 may accommodate the battery module 200.

The pack housing 100 may include an electrical component housing 120. The electrical component housing 120 may be formed with a hollow structure. The electrical component housing 120 may be openable in one direction. In some embodiments, the electrical component housing 120 may be configured to be openable in an upward direction. The electrical component housing 120 may accommodate the electrical component 300.

The pack housing 100 may include a pump case 130. The pump case 130 may be formed with a hollow structure. The pump case 130 may be openable in one direction. In some embodiments, the pump case 130 may be configured to be openable in an upward direction. The pump case 130 may accommodate the built-in pump 400.

The pack housing 100 may include a first valve 500. The first valve 500 may connect the battery module housing 110 and the pump case 130. The first valve 500 may be configured to adjust a flow rate of the coolant between the battery module housing 110 and the pump case 130. In some embodiments, the first valve 500 may be configured to adjust the flow of coolant from the pump case 130 to the battery module housing 110.

The battery module 200 seated in the battery module housing 110 and the electrical component 300 seated in the electrical component housing 120 may be separately immersion-cooled. In some embodiments, the built-in pump 400 and the first valve 500 may be disposed between the battery module housing 110 and the electrical component housing 120. In some embodiments, the battery module housing 110 and the electrical component housing 120 may be connected via the built-in pump 400 and the first valve 500.

The coolant flowing into the electrical component housing 120 may perform cooling of the electrical component 300. The coolant that has passed through the electrical component housing 120 may flow into the battery module housing 110 through the built-in pump 400 and the first valve 500. Accordingly, the battery module 200 and the electrical component 300 may be separately immersion-cooled in their respective separate spaces.

As described above, in addition to the space for cooling the battery module 200, a space for cooling the electrical component 300 may be independently formed. Conventionally, since the battery module 200 and the electrical component 300 were disposed in the same space, there was a problem that the required installation space was increased due to the use of a large-sized bus bar.

Meanwhile, according to the present disclosure, since the battery module 200 and the electrical component 300 are separated, the electrical component 300 may be miniaturized by reducing the size of the bus bar. In some embodiments, as separate immersion cooling is additionally applied to the electrical component 300, the use of a large-sized bus bar, which was conventionally used to account for heat generation, may be suppressed.

The present disclosure may enhance the space efficiency of a vehicle by integrating the electrical component 300 with the electrical component housing 120. In some embodiments, by accommodating the electrical component 300 in the electrical component housing 120, which conventionally served only as a coolant storage space, separate cooling and space utilization of the electrical component 300 may be enhanced.

The battery pack cooling system 1 may include a cooler 20. The cooler 20 may function to cool the coolant that has been heated during the cooling process inside the battery pack 10. The cooler 20 may be configured to enable heat exchange for the heated coolant through a heat exchanger device.

The battery pack cooling system 1 may include a reservoir tank 30. The reservoir tank 30 may temporarily store the coolant discharged from the battery pack 10. The reservoir tank 30 may perform a purification or filtration process of the coolant containing impurities during the immersion cooling process of the battery pack 10. In some embodiments, the reservoir tank 30 may filter particles contained in the coolant.

Venting gas generated during the circulation process of the coolant may be discharged through the reservoir tank 30. In some embodiments, the venting gas within the reservoir tank 30 may be released to the outside at atmospheric pressure.

The battery pack cooling system 1 may include an external pump 40. The external pump 40 may be disposed between the cooler 20 and the reservoir tank 30. In some embodiments, the external pump 40 may be configured to enable the flow of coolant between the reservoir tank 30 and the cooler 20. For instance, the external pump 40 may allow the coolant discharged from the reservoir tank 30 to flow to the cooler 20.

The battery pack cooling system 1 may include a second valve 50. The second valve 50 may connect the battery pack 10 and the reservoir tank 30. In some embodiments, the second valve 50 may be configured to enable the flow of the coolant between the battery pack 10 and the reservoir tank 30. In some embodiments, the second valve 50 may allow the coolant to flow between the battery module housing 110 and the reservoir tank 30.

The battery pack cooling system 1 may include a circulation flow path 60. The circulation flow path 60 may refer to a coolant flow line centered around the battery pack 10. The circulation flow path 60 may include a circulation supply flow path 61. The circulation supply flow path 61 may penetrate the electrical component housing 120. In some embodiments, the circulation supply flow path 61 may penetrate the front and rear surfaces of an electrical component housing body 121.

The circulation supply flow path 61 may be connected to the cooler 20 and the electrical component housing 120. In some embodiments, the circulation supply flow path 61 may be configured to deliver the coolant, cooled and filtered in the cooler 20, to the electrical component housing 120. The circulation supply flow path 61 may serve as a coolant supply line for the battery pack 10.

The circulation flow path 60 may include a circulation discharge flow path 62. The circulation discharge flow path 62 may penetrate the battery module housing 110. In some embodiments, the circulation discharge flow path 62 may penetrate a battery module housing body left side portion 111SL.

The coolant may sequentially flow from the circulation supply flow path 61 to the electrical component housing 120, the battery module housing 110, and the circulation discharge flow path 62. Through this, individual cooling may be performed separately for the electrical component housing 120 and the battery module housing 110.

Meanwhile, the circulation discharge flow path 62 may be symmetrically arranged with respect to the second battery pack cooling flow path 620 centered on the battery module 200. In some embodiments, the circulation discharge flow path 62 may penetrate a battery module housing body rear portion 111R.

The circulation discharge flow path 62 may be connected to the second valve 50 and the battery module housing 110. In some embodiments, the circulation discharge flow path 62 may be configured to deliver the coolant, heated in the battery module housing 110, to the second valve 50.

The circulation discharge flow path 62 may serve as a coolant discharge line of the battery pack 10. Meanwhile, the circulation discharge flow path 62 may be connected to the battery module housing 110 and the reservoir tank 30.

The second valve 50 may be located in the circulation discharge flow path 62. The second valve 50 may control the flow rate of coolant flowing through the circulation discharge flow path 62 by adjusting the degree of opening of the circulation discharge flow path 62.

The circulation flow path 60 may include a circulation intermediate flow path 63. The circulation intermediate flow path 63 may connect the second valve 50, the reservoir tank 30, the external pump 40 and the cooler 20.

The circulation intermediate flow path 63 may include a plurality of circulation flow paths. The plurality of circulation flow paths may be sequentially connected from the second valve 50 to the reservoir tank 30, the external pump 40 and the cooler 20.

In some embodiments, the plurality of circulation flow paths may include a first circulation flow path that connects the second valve 50 and the reservoir tank 30, a second circulation flow path that connects the reservoir tank 30 and the external pump 40, and a third circulation flow path that connects the external pump 40 and the cooler 20.

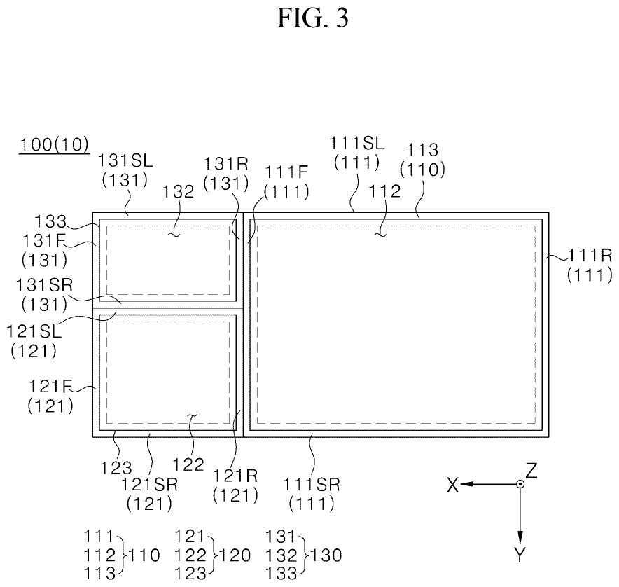

Referring to FIGS. 2 and 3, the pack housing 100 may be formed to extend in one direction. In some embodiments, the pack housing 100 may be formed to extend in the front-back direction. The longitudinal direction of the pack housing 100 may be parallel to the front-back direction. The lateral direction of the pack housing 100 may be parallel to the left-right direction. The thickness direction of the pack housing 100 may be parallel to the up-down direction.

The pack housing 100 may include the battery module housing 110. The battery module housing 110 may form a part of the pack housing 100. In some embodiments, the battery module housing 110 may form a rear portion of the pack housing 100.

The battery module housing 110 may include a battery module housing body 111. In some embodiments, the battery module housing body 111 may be formed in the shape of a hollow rectangular frame.

The battery module housing body 111 may include a battery module housing body front portion 111F. The battery module housing body front portion 111F may be located in front of the battery module 200. The battery module housing body 111 may include the battery module housing body rear portion 111R. The battery module housing body rear portion 111R may be located behind the battery module 200.

The battery module housing body front portion 111F and the battery module housing body rear portion 111R may be spaced apart from each other. In some embodiments, the battery module housing body front portion 111F may be located in front of the battery module housing body rear portion 111R.

The battery module housing body 111 may include the battery module housing body left side portion 111SL. The battery module housing body left side portion 111SL may be located on the left side of the battery module 200.

The battery module housing body 111 may include a battery module housing body right side portion 111SR. The battery module housing body right side portion 111SR may be located on the right side of the battery module 200. The battery module housing body left side portion 111SL and the battery module housing body right side portion 111SR may be spaced apart from each other.

The battery module housing body front portion 111F, the battery module housing body left side portion 111SL, the battery module housing body rear portion 111R, and the battery module housing body right side portion 111SR may form a peripheral portion of the battery module housing 110.

The battery module housing body front portion 111F, the battery module housing body left side portion 111SL, the battery module housing body rear portion 111R, and the battery module housing body right side portion 111SR may be sequentially connected.

The battery module housing body 111 may include a battery module housing body bottom portion 111B. The battery module housing body bottom portion 111B may form a bottom surface of the battery module housing 110.

The battery module housing 110 may include a module housing body receiving part 112. The module housing body receiving part 112 may define a space in which the battery module 200 is placed. The module housing body receiving part 112 may define a space in which the coolant is stored.

The battery module housing 110 may include a module housing body door 113. The module housing body door 113 may be disposed at an open upper portion of the battery module housing 110.

The module housing body door 113 may be pivotably coupled to an upper end of the battery module housing body 111. In some embodiments, the module housing body door 113 may be hingedly coupled to an upper end of the battery module housing body rear portion 111R. The battery module housing 110 may be opened upward by pivoting the module housing body door 113.

This may facilitate easy access to the battery module 200 disposed within the battery module housing 110 may be facilitated. That is, in the event of an abnormality in the battery module 200 accommodated within the battery module housing 110, the module housing body door 113 may enable immediate maintenance of the battery module 200.

The pack housing 100 may include the electrical component housing 120. The electrical component housing 120 may form a part of the pack housing 100. In some embodiments, the electrical component housing 120 may form a front portion of the pack housing 100. In some embodiments, the electrical component housing 120 may be located in front of the battery module housing 110.

The electrical component housing 120 may include the electrical component housing body 121. In some embodiments, the electrical component housing body 121 may be formed in the shape of a hollow rectangular frame. The electrical component housing body 121 may include an electrical component housing body front portion 121F. The electrical component housing body front portion 121F may be located in front of the electrical component 300.

The electrical component housing body 121 may include an electrical component housing body rear portion 121R. The electrical component housing body rear portion 121R may be located behind the electrical component 300. The electrical component housing body front portion 121F and the electrical component housing body rear portion 121R may be spaced apart from each other. In some embodiments, the electrical component housing body front portion 121F may be located in front of the electrical component housing body rear portion 121R.

The electrical component housing body rear portion 121R and the battery module housing body front portion 111F may be connected in the front-back direction. The electrical component housing body rear portion 121R may be located in front of the battery module housing body front portion 111F. The electrical component housing body rear portion 121R and the battery module housing body front portion 111F may be integrally formed.

The electrical component housing body 121 may include an electrical component housing body left side portion 121SL. The electrical component housing body left side portion 121SL may be located on the left side of the electrical component 300.

The electrical component housing body 121 may include an electrical component housing body right side portion 121SR. The electrical component housing body right side portion 121SR may be located on the right side of the electrical component 300. The electrical component housing body left side portion 121SL and the electrical component housing body right side portion 121SR may be spaced apart from each other.

The electrical component housing body right side portion 121SR and the battery module housing body right side portion 111SR may be aligned in a straight line along the front-back direction. In some embodiments, the electrical component housing body right side portion 121SR and the battery module housing body right side portion 111SR may form a right side surface of the pack housing 100.

The electrical component housing body front portion 121F, the electrical component housing body left side portion 121SL, the electrical component housing body rear portion 121R, and the electrical component housing body right side portion 121SR may form a peripheral portion of the electrical component housing 120.

The electrical component housing body front portion 121F, the electrical component housing body left side portion 121SL, the electrical component housing body rear portion 121R, and the electrical component housing body right side portion 121SR may be sequentially connected to form the electrical component housing 120.

A bottom surface of the body of the electrical component housing 120 may be shared with the bottom surface of the battery module housing 110. In some embodiments, the battery module housing body bottom portion 111B may form a part of the bottom surface of the body of the electrical component housing 120.

The electrical component housing 120 may include an electrical component housing body door 123. The electrical component housing body door 123 may be disposed at an open upper portion of the electrical component housing 120.

The electrical component housing body door 123 may be pivotally coupled to an upper end of the electrical component housing body 121. In some embodiments, the electrical component housing body door 123 may be hingedly coupled to an upper end of the electrical component housing body front portion 121F.

The electrical component housing 120 may be opened upward by pivoting the electrical component housing body door 123. This may facilitate easy access to the electrical component 300 disposed within the electrical component housing 120.

In the event of an abnormality in the electrical component 300 accommodated within the electrical component housing 120, the electrical component housing body door 123 may enable immediate maintenance of the electrical component 300. That is, when the electrical component housing 120 accommodates only the electrical component 300, maintenance may be performed solely based on the presence or absence of an abnormality in the electrical component 300, regardless of the presence or absence of a problem in the battery module 200.

In addition, as the demand for fast charging of the battery pack increases, electrical components connected to the battery module 200 may be overloaded. Accordingly, efficient cooling of the electrical component 300 may be required.

The pack housing 100 may include the pump case 130. The pump case 130 may form a part of the pack housing 100. In some embodiments, the pump case 130 may form a front portion of the pack housing 100.

The pump case 130 may include a pump case body 131. In some embodiments, the pump case body 131 may be formed in the shape of a hollow square frame. The pump case body 131 may include a pump case body front portion 131F. The pump case body front portion 131F may be located in front of the built-in pump 400.

The pump case body 131 may include a pump case body rear portion 131R. The pump case body rear portion 131R may be located behind the built-in pump 400. The pump case body front portion 131F and the pump case body rear portion 131R may be spaced apart from each other. In some embodiments, the pump case body front portion 131F may be located in front of the pump case body rear portion 131R.

The pump case body rear portion 131R and the battery module housing body front portion 111F may be connected in the front-back direction. The pump case body rear portion 131R may be located in front of the battery module housing body front portion 111F. The pump case body rear portion 131R and the battery module housing body front portion 111F may be integrally formed.

The pump case body 131 may include a pump case body left side portion 131SL. The pump case body left side portion 131SL may be located on the left side of the built-in pump 400.

The electrical component housing body 121 may include a pump case body right side portion 131SR. The pump case body right side portion 131SR may be located on the right side of the built-in pump 400. The pump case body left side portion 131SL and the pump case body right side portion 131SR may be spaced apart from each other.

The pump case body left side portion 131SL and the battery module housing body left side portion 111SL may be aligned in a straight line along the front-back direction. In some embodiments, the pump case body left side portion 131SL and the battery module housing body left side portion 111SL may form a left side of the pack housing 100.

The pump case body front portion 131F, the pump case body left side portion 131SL, the pump case body rear portion 131R, and the pump case body right side portion 131SR may form a peripheral portion of the pump case 130.

The pump case body front portion 131F, the pump case body left side portion 131SL, the pump case body rear portion 131R, and the pump case body right side portion 131SR may be sequentially connected to form the pump case 130. The bottom surface of the pump case 130 may be shared with the bottom surface of the battery module housing 110. In some embodiments, the battery module housing body bottom portion 111B may form a part of the bottom surface of the pump case 130.

The pump case 130 may include a pump case body door 133. The pump case body door 133 may be disposed at an open upper portion of the pump case 130. The pump case body door 133 may be pivotably coupled to an upper end of the pump case body 131.

In some embodiments, the pump case body door 133 may be hingedly coupled to an upper end of the pump case body front portion 131F. In some embodiments, the pump case body door 133 may be hingedly coupled to an upper end of the pump case body front portion 131F.

The pump case 130 may be opened upward by pivoting the pump case body door 133. This may facilitate easy access to the built-in pump 400 disposed within the pump case 130.

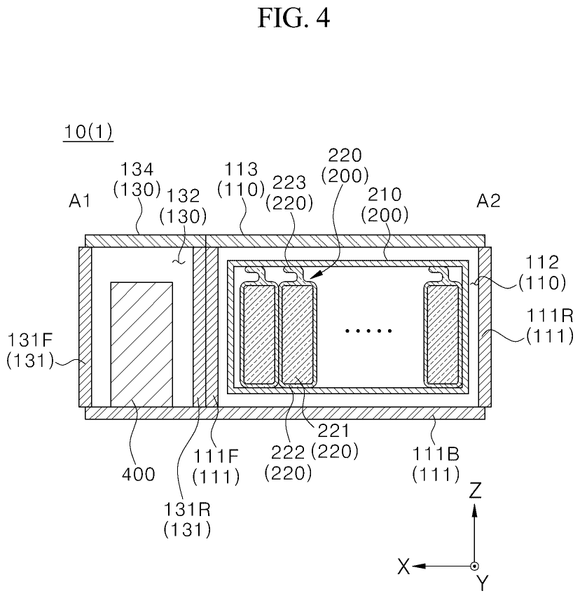

Referring to FIGS. 2 and 4, the battery module 200 may include a battery module case 210. The battery module case 210 may be formed to extend in one direction. In some embodiments, the battery module case 210 may be formed to extend in the front-back direction.

The battery module 200 may include the battery cells 220. The battery cells 220 may be stacked in the front-back direction. The battery cells 220 may also be stacked in the thickness direction of each battery cell 220. Each battery cell 220 may include an electrode assembly 221, an outer case 222 that encloses the electrode assembly 221, and a sealing part 223 formed on one side of the outer case 222.

The battery pack 10 may include a battery pack cooling flow path 600. The battery pack cooling flow path 600 may include a first battery pack cooling flow path 610. The first battery pack cooling flow path 610 may connect the electrical component 300 and the built-in pump 400. The first battery pack cooling flow path 610 may pass through the electrical component housing body left side portion 121SL and the pump case body right side portion 131SR.

The battery pack cooling flow path 600 may include a second battery pack cooling flow path 620. The second battery pack cooling flow path 620 may connect the built-in pump 400 and the battery module housing 110. The second battery pack cooling flow path 620 may pass through the pump case body rear portion 131R and the battery module housing body front portion 111F.

The first valve 500 may be disposed in the second battery pack cooling flow path 620. In some embodiments, the first valve 500 may be configured to adjust the flow rate of the coolant from the built-in pump 400 to the battery module housing 110.

The second battery pack cooling flow path 620 and the circulation discharge flow path 62 may be arranged at the front and rear of the battery module 200. The coolant introduced into the battery module housing 110 through the second battery pack cooling flow path 620 may be discharged from the battery module housing 110 through the circulation discharge flow path 62.

In some embodiments, the coolant introduced into the battery module housing 110 may enable uniform and continuous cooling of the plurality of battery cells 220 that form the battery module 200 in the front-back direction.

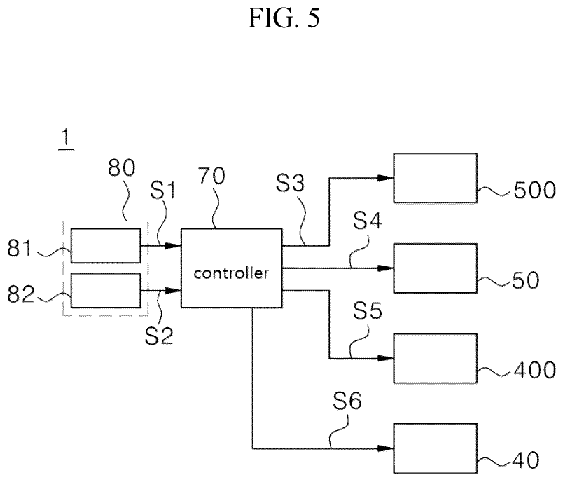

FIG. 5 is a block diagram illustrating the battery pack cooling system 1 according to an embodiment of the present disclosure. Referring to FIG. 5, the battery pack cooling system 1 according to an embodiment of the present disclosure may include a controller 70.

The controller 70 may perform computations. The controller 70 may process signals. The battery pack cooling system 1 may include a sensor unit 80. The sensor unit 80 may measure physical quantities within the battery pack 10. In some embodiments, the sensor unit 80 may measure physical quantities including temperature, flow rate, pressure, and the like within the battery pack 10.

In some embodiments, the sensor unit 80 may measure the temperature of the coolant flowing through the battery pack 10 in real time. In some embodiments, the controller 70 may receive the temperature of the coolant flowing through the battery pack 10 in real time from the sensor unit 80. As a result, the controller 70 may compare the received temperature with the upper limit temperature preset therein.

The sensor unit 80 may include a first sensor 81. The first sensor 81 may be disposed in the battery module housing 110. In some embodiments, the first sensor 81 may measure the temperature of the coolant flowing through the module housing body receiving part 112 of the battery module housing 110 in real time.

The sensor unit 80 may include a second sensor 82. The second sensor 82 may be disposed in the electrical component housing 120. In some embodiments, the second sensor 82 may measure the temperature of the coolant flowing through the electrical component 300, which is seated in the electrical component housing 120, in real time.

In some embodiments, the controller 70 may receive input signals S1 and S2, and generate output signals S3, S4, S5 and S6 based on the input signals S1 and S2. The input signals S1 and S2 may include or refer to at least one of a first signal S1 and a second signal S2.

The output signals S3, S4, S5 and S6 may include or refer to at least one of a third signal S3, a fourth signal S4, a fifth signal S5, and a sixth signal S6.

The first sensor 81 may generate the first signal S1 regarding input and transmit it to the controller 70. The first signal S1 may include information regarding the temperature measurement value of the coolant supplied to the battery module housing 110. The coolant supplied to the battery module housing 110 may perform immersion cooling for the battery module 200.

The second sensor 82 may generate the second signal S2 regarding input and transmit it to the controller 70. The second signal S2 may include information regarding the temperature measurement value of the coolant supplied to the electrical component housing 120. The coolant supplied to the electrical component housing 120 may perform immersion cooling for the electrical component 300.

The controller 70 may generate the third signal S3 based on the input signals S1 and S2. In some embodiments, the controller 70 may generate the third signal S3 based on the first signal S1. The controller 70 may obtain the temperature of the coolant in the battery module housing 110 through the first signal S1.

The controller 70 may set a first limit temperature, which is the upper limit temperature of the coolant in the battery module housing 110, for the stable operation of the battery module 200 contained in the battery module housing 110.

The third signal S3 may include adjustment information for the first valve 500. The controller 70 may compare the temperature of the coolant in the battery module housing 110 obtained through the first signal S1 with the first limit temperature preset in the controller 70. The degree of opening of the first valve 500 may be controlled based on the compared temperature information.

The controller 70 may generate the fourth signal S4 based on the input signals S1 and S2. In some embodiments, the controller 70 may generate the fourth signal S4 based on the second signal S2. The controller 70 may obtain the temperature of the coolant in the electrical component 300 through the second signal S2. The fourth signal S4 may include adjustment information for the second valve 50.

The controller 70 may compare the temperature of the coolant in the electrical component 300 obtained through the second signal S2 with the first limit temperature preset in the controller 70. The degree of opening of the second valve 50 may be controlled based on the compared temperature information.

That is, the flow of the coolant stored in the battery module housing 110 may be adjusted by controlling the first valve 500 and the second valve 50 centered on the battery module housing 110. Therefore, the temperature of the coolant stored in the battery module housing 110 may also be adjusted.

The controller 70 may generate the fifth signal S5 based on the input signals S1 and S2. In some embodiments, the controller 70 may obtain the temperature of the coolant in the battery module housing 110 and the electrical component 300 through the input signals S1 and S2.

The controller 70 may operate the built-in pump 400 for the stable operation of the battery module 200 and the electrical component 300. In some embodiments, the coolant stored in the electrical component housing 120 may be pumped to the battery module housing 110.

The controller 70 may generate the sixth signal S6 based on the input signals S1 and S2. In some embodiments, the controller 70 may obtain the temperature of the coolant in the battery module housing 110 and the electrical component 300 through the input signals S1 and S2.

The controller 70 may operate the external pump 40 for the stable operation of the battery module 200 and the electrical component 300. In some embodiments, the coolant stored in the reservoir tank 30 may be pumped to the cooler 20.

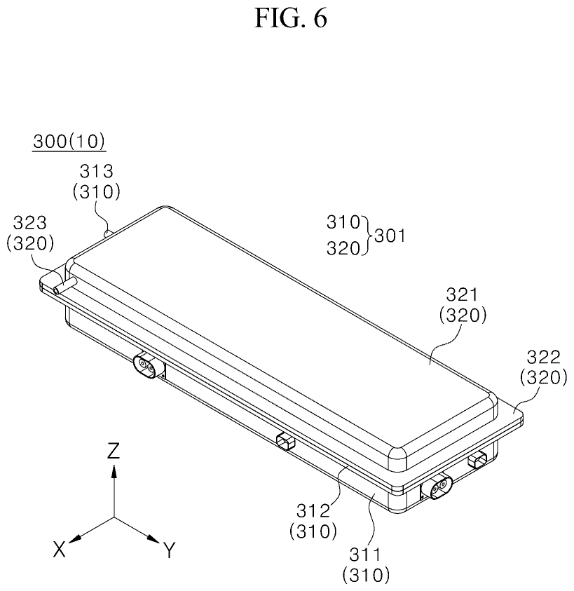

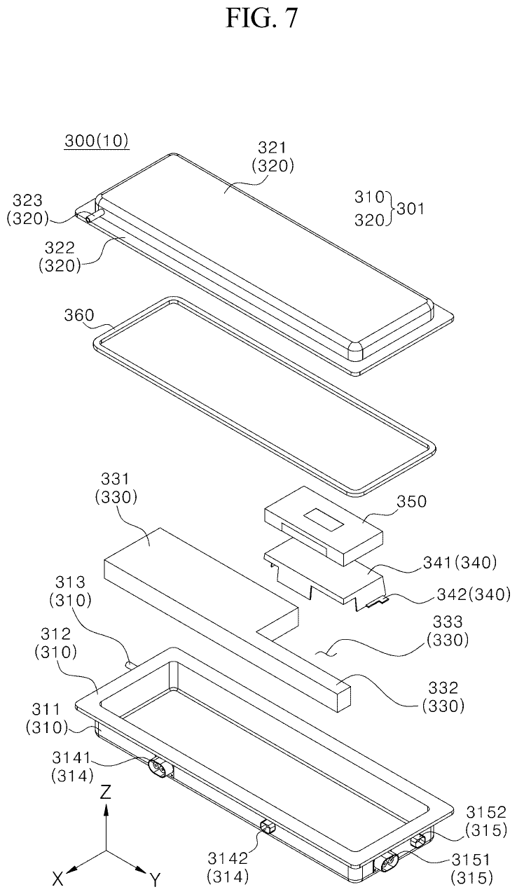

Referring to FIGS. 6 and 7, the longitudinal direction of the electrical component 300 may be parallel to the left-right direction. In some embodiments, the longitudinal direction of the electrical component 300 may be parallel to the lateral direction of the battery pack 10.

The electrical component 300 may include an electrical component case 301. The electrical component case 301 may be formed with a hollow structure. The electrical component case 301 may be formed to extend in one direction. The electrical component case 301 may be formed to extend in the left-right direction.

The longitudinal direction of the electrical component case 301 may be parallel to the left-right direction. In some embodiments, the longitudinal direction of the electrical component case 301 may be parallel to the lateral direction of the battery pack 10. Front and rear surfaces of the electrical component case 301 may be arranged in the front-back direction. Left and right side surfaces of the electrical component case 301 may be arranged in the left-right direction.

The electrical component case 301 may include a lower case 310. The lower case 310 may be configured to be openable in an upward direction. In some embodiments, the lower case 310 may be formed in a convex shape facing downward. In some embodiments, the lower case 310 may be formed in a rectangular parallelepiped shape with a top opening.

The lower case 310 may include a lower case body 311 and a lower case body flange 312. The lower case body 311 may be formed in a rectangular parallelepiped shape with a top opening.

The lower case body flange 312 may be connected or coupled to an upper end of the lower case body 311. In some embodiments, the lower case body flange 312 may extend outwardly from the upper end of the lower case body 311.

The lower case 310 may include a coolant outlet 313. The coolant outlet 313 may be connected or coupled to the lower case body 311. In some embodiments, the coolant outlet 313 may be disposed through a left side surface of the lower case body 311.

The lower case 310 may include an input connector 314. The input connector 314 may electrically connect an external device to the electrical component 300. The input connector 314 may include a first high voltage connector 3141.

The first high voltage connector 3141 may connect a power relay assembly (PRA) 330 to a drive motor. The input connector 314 may include a first low voltage connector 3142. The first low voltage connector 3142 may connect a battery management system 350 to a vehicle.

The lower case 310 may include an output connector 315. The output connector 315 may electrically connect the electrical component 300 to the battery module 200. The output connector 315 may include a second high voltage connector 3151. The second high voltage connector 3151 may connect the power relay assembly 330 to the battery module 200.

The output connector 315 may include a second low voltage connector 3152. The second low voltage connector 3152 may connect the battery management system 350 to a cell management unit (CMU) of the battery module 200. Numerous sensors may be required to measure data such as temperature, voltage, and the like for the battery cells 220 that form the battery module 200. The cell management unit may manage the numerous sensors by grouping them into a single module.

The output connector 315 may connect the electrical component 300 to the battery module 200 through the bottom surface of the battery pack 10. In some embodiments, the output connector 315 may be embedded in the battery module housing body bottom portion 111B. In some embodiments, the output connector 315 may include a bus bar structure embedded in the bottom surface of the pack housing 100.

The electrical component case 301 may include an upper case 320. The upper case 320 may be configured to be openable in a downward direction. In some embodiments, the upper case 320 may be formed in an convex shape facing upward. In some embodiments, the upper case 320 may be formed in a rectangular parallelepiped shape with a bottom opening.

The upper case 320 may have a coolant inlet 323 connected to the circulation supply flow path 61.

The upper case 320 may include an upper case body 321 and an upper case body flange 322. The upper case body 321 may be formed in a rectangular parallelepiped shape with a bottom opening. The upper case body flange 322 may be connected or coupled to a lower end of the upper case body 321. In some embodiments, the upper case body flange 322 may extend outwardly from the lower end of the upper case body 321.

The electrical component 300 may include the power relay assembly 330. The power relay assembly 330 may be disposed within the electrical component case 301. The power relay assembly 330 may include a power relay assembly body 331 and a power relay assembly protrusion 332 that extends from one side of the power relay assembly body 331.

In some embodiments, the power relay assembly body 331 and the power relay assembly protrusion 332 may be aligned in a row along the longitudinal direction of the electrical component case 301. Meanwhile, the power relay assembly protrusion 332 may be eccentrically disposed on one side of the power relay assembly body 331. In some embodiments, the power relay assembly protrusion 332 may extend in the longitudinal direction of the electrical component case 301 from one edge of the power relay assembly body 331.

The power relay assembly 330 may include a power relay assembly recess 333. The power relay assembly recess 333 may be formed as a recessed portion open to both the upper and lower surfaces of the power relay assembly 330. The power relay assembly recess 333 may extend continuously from the upper surface to the lower surface of the power relay assembly 330.

The power relay assembly recess 333 may be connected to the power relay assembly body 331 and the power relay assembly protrusion 332. The boundary of the power relay assembly recess 333 may be formed by a part of an outer surface of the power relay assembly body 331 and a part of an outer surface of the power relay assembly protrusion 332.

The electrical component 300 may include a bracket 340. The bracket 340 may be located in the power relay assembly recess 333. The bracket 340 may include a bracket body 341. The bracket body 341 may be formed in the shape of a plate or board.

The bracket 340 may include bracket legs 342. The bracket legs 342 may be connected or coupled to the bracket body 341. In some embodiments, the bracket legs 342 may extend downward from a lower end of the bracket body 341.

The bracket legs 342 may be elastically connected to the bracket body 341. In some embodiments, the bracket legs 342 may be hingedly coupled to the bracket body 341. In this way, the height of the bracket 340 may be adjusted by controlling the connection angle of the bracket legs 342.

The electrical component 300 may include the battery management system 350. The battery management system 350 may be connected to or seated on the bracket 340. In some embodiments, the battery management system 350 may be seated on top of the bracket body 341. As a result, the battery management system 350 is supported by the bracket 341.

In this way, the battery management system 350 may be located in the power relay assembly recess 333. As a result, the battery management system 350 may be cooled in a region that is thermally isolated from the power relay assembly 330.

The power relay assembly 330 and the battery management system 350 may be disposed along the longitudinal direction of the electrical component case 301. Thus, the coolant introduced into the electrical component case 301 and flowing in the longitudinal direction of the electrical component case 301 may sequentially and continuously cool the power relay assembly 330 and the battery management system 350.

The electrical component 300 may include a gasket 360. The gasket 360 may be disposed between the lower case 310 and the upper case 320. The gasket 360 may seal between the lower case 310 and the upper case 320. The gasket 360 may prevent leakage of coolant introduced into the electrical component case 301.

The battery pack and the cooling system including the same according to the above-described embodiment of the present disclosure have been described as specific embodiments, but these are merely illustrative. The present disclosure is not limited to the above embodiments and should be interpreted as having the broadest scope in accordance with the basic concept disclosed in this specification.

What is claimed is:

1. A battery pack comprising:
a pack housing configured to receive coolant for immersion cooling;
a battery module accommodated within the pack housing; and
an electrical component accommodated within the pack housing and disposed separately from the battery module,
wherein the pack housing comprises:
a battery module housing configured to accommodate the battery module; and
an electrical component housing configured to accommodate the electrical component,
wherein the coolant flows through the battery module housing and the electrical component housing.

2. The battery pack according to claim 1, further comprising a built-in pump accommodated in a pump case that forms part of the pack housing; and
a first valve configured to adjust the flow rate of the coolant between the built-in pump and the battery module housing.

3. The battery pack according to claim 1, further comprising a circulation flow path connected to the pack housing and through which the coolant flows,
wherein the circulation flow path comprises:
a circulation supply flow path connected to the electrical component housing; and
a circulation discharge flow path connected to the battery module housing.

4. The battery pack according to claim 3, wherein the coolant sequentially flows through the circulation supply flow path, the electrical component housing, the battery module housing, and the circulation discharge flow path.

5. The battery pack according to claim 4, wherein the electrical component housing is located in front of the battery module housing.

6. The battery pack according to claim 3, further comprising a battery pack cooling flow path disposed within the pack housing,
wherein the battery pack cooling flow path comprises:
a first battery pack cooling flow path configured to connect the electrical component to the built-in pump; and
a second battery pack cooling flow path configured to connect the built-in pump to the battery module housing.

7. The battery pack according to claim 6, wherein the first valve is located in the second battery pack cooling flow path.

8. The battery pack according to claim 1, wherein the pack housing comprises a door openably coupled to an open upper portion thereof,
wherein the door comprises:
a module housing body door disposed at an open upper portion of the battery module housing; and
an electrical component housing body door disposed at an open upper portion of the electrical component housing.

9. The battery pack according to claim 6, wherein the electrical component comprises:
an electrical component case connected to the circulation supply flow path and configured to receive the coolant;
a power relay assembly accommodated within the electrical component case; and
a battery management system disposed adjacent to the power relay assembly.

10. The battery pack according to claim 9, wherein the battery management system is disposed in a power relay assembly recess formed in the power relay assembly.

11. The battery pack according to claim 10, wherein the electrical component case comprises:
a lower case having a coolant outlet connected to the first battery pack cooling flow path; and
an upper case coupled to an open upper portion of the lower case and having a coolant inlet connected to the circulation supply flow path.

12. The battery pack according to claim 10, wherein the electrical component comprises a bracket disposed in the power relay assembly recess, and
the battery management system is supported by the bracket.

13. The battery pack according to claim 5, wherein the battery module comprises:
a battery module case; and
battery cells accommodated in the battery module case,
wherein the battery cells are stacked in a front-back direction.

14. The battery pack according to claim 1, wherein the battery module housing and the electrical component housing are disposed adjacent to each other.

15. The battery pack according to claim 14, wherein the electrical component and the battery module are connected by a bus bar embedded in a bottom surface of the pack housing.

16. A battery pack cooling system comprising:
a battery pack configured to separately accommodate a battery module and an electrical component electrically connected to the battery module, and to receive coolant for immersion cooling;
a circulation flow path connected to the battery pack;
a cooler disposed in the circulation flow path and configured to cool the coolant; and
a reservoir tank disposed in the circulation flow path and configured to store the coolant discharged from the battery pack.

17. The battery pack cooling system according to claim 16, wherein the circulation flow path comprises:
a circulation supply flow path connected to the electrical component; and
a circulation discharge flow path connected to a battery module housing configured to accommodate the battery module.

18. The battery pack cooling system according to claim 17, further comprising a second valve disposed in the circulation discharge flow path,
wherein the second valve is configured to adjust a flow rate of the coolant between the battery module housing and the reservoir tank.

19. The battery pack cooling system according to claim 16, wherein the battery pack comprises a pack housing configured to separately accommodate the battery module and the electrical component,
wherein the pack housing comprises a battery module housing configured to accommodate the battery module; and an electrical component housing configured to accommodate the electrical component,
wherein the coolant flows through the battery module housing, the circulation flow path, and the electrical component housing.

20. The battery pack cooling system according to claim 19, wherein the pack housing comprises a door openably coupled to an open upper portion thereof,
wherein the door comprises:
a module housing body door disposed at an open upper portion of the battery module housing; and
an electrical component housing body door disposed at an open upper portion of the electrical component housing.
